(19) United States
(12) Patent Application Publication
(10) Pub. No.: US 2025/0096751 A1
(43) Pub. Date: Mar. 20, 2025

(54) Darlington Circuit with a Driver Amplifier

(71) Applicant: Qualcomm Incorporated, San Diego, CA (US)

(72) Inventors: Lei Ma, Palo Alto, CA (US); Antonino Scuderi, San Diego, CA (US)

(21) Appl. No.: 18/470,024

(22) Filed: Sep. 19, 2023

(51) Int. Cl. H03F 3/24; H03F 1/30; H03F 1/52

(52) U.S. Cl. CPC H03F 3/245; H03F 1/302; H03F 1/52; H03F 2200/294; H03F 2200/451; H03F 2200/93

(57) ABSTRACT

An apparatus is disclosed for implementing a Darlington circuit with a driver amplifier to provide power clamping. In example aspects, the apparatus includes an amplifier circuit having an input port and an output port. The amplifier circuit includes a driver amplifier, a power amplifier, and a Darlington circuit. The driver amplifier includes a driver amplifier output and a transistor, with the driver amplifier coupled between the input port and the output port. The power amplifier includes a power amplifier input, and the power amplifier is coupled between the driver amplifier output and the output port. The Darlington circuit is coupled to the driver amplifier via a node that is coupled between the input port and the power amplifier input.

### TECHNICAL FIELD

This disclosure relates generally to signal communication or signal processing using an electronic device and, more specifically, to employing a Darlington circuit with a driver amplifier.

### BACKGROUND

Electronic devices include traditional computing devices such as desktop computers, notebook computers, smartphones, wearable devices like a smartwatch, internet servers, and so forth. Electronic devices also include other types of computing devices such as personal voice assistants (e.g., smart speakers), wireless access points or routers, thermostats and other automated controllers, robotics, automotive electronics, devices embedded in other machines like refrigerators and industrial tools, Internet of Things (IoT) devices, medical devices, and so forth. These various electronic devices provide services relating to productivity, communication, social interaction, security, health and safety, remote management, entertainment, transportation, and information dissemination. Thus, electronic devices play crucial roles in modern society.

Many of the services provided by electronic devices in today's interconnected world depend at least partly on electronic communications. Electronic communications can include, for example, those exchanged between two or more electronic devices using wireless or wired signals that are transmitted over one or more networks, such as the Internet, a Wi-Fi® network, or a cellular network. Electronic communications can therefore include wireless or wired transmissions and receptions. To transmit and receive communications, an electronic device can use a transceiver, such as a wireless transceiver that is designed for wireless communications.

Electronic communications can therefore be realized by propagating signals between two wireless transceivers at two different electronic devices. For example, using a wireless transmitter, a smartphone can transmit a wireless signal to a base station over the air as part of an uplink communication to support mobile services. Using a wireless receiver, the smartphone can receive a wireless signal that is transmitted from the base station via the air medium as part of a downlink communication to enable mobile services. With a smartphone, mobile services can include making voice and video calls, participating in social media interactions, sending messages, watching movies, sharing videos, and performing searches. Other mobile services can include using map information or navigational instructions, finding friends, engaging in location-based services generally, transferring money, obtaining another service like a car ride, and so forth.

Many of these mobile services depend at least partly on the transmission or reception of wireless signals between two or more electronic devices. Consequently, researchers, electrical engineers, and designers of electronic devices strive to develop wireless transceivers and other wireless hardware that can use wireless signals effectively to provide these and other mobile services.

### SUMMARY

A power clamp can protect the components of a wireless interface device. In one approach, a power clamp is employed on a controller die to protect a power amplifier on a different integrated circuit die or chip. The routing distance between such a power clamp on the controller die and a power amplifier on an amplifier die, however, is sufficient to degrade the actual power clamping to a level that is below a targeted power clamping protection threshold. To shorten this routing distance and at least reduce the disparity between a targeted and an actual protection level, this document describes employing a Darlington circuit with a driver amplifier to provide power clamping, including to provide protection for the power amplifier. In example implementations, an integrated circuit chip can include an amplifier circuit having a driver amplifier that feeds a power amplifier. The integrated circuit chip also includes a Darlington circuit that is coupled to the driver amplifier via a node, such a power distribution node for a transistor of the driver amplifier. In example operations, multiple diodes and two or more transistors that are arranged in a Darlington configuration can clamp a voltage level of the node. The Darlington circuit can also clamp a current flowing through the transistor of the driver amplifier. The circuitry can additionally provide electrostatic discharge (ESD) protection. Thus, the Darlington circuit can provide power clamping for the amplifier circuit, including for the power amplifier that is coupled “downstream” of an output of the driver amplifier. Further, the power clamping can be achieved while having an appreciably shorter routing distance between the power clamp and the power amplifier.

In an example aspect, an apparatus is disclosed. The apparatus includes an amplifier circuit having an input port and an output port. The amplifier circuit includes a driver amplifier, a power amplifier, and a Darlington circuit. The driver amplifier includes a driver amplifier output and a transistor, with the driver amplifier coupled between the input port and the output port. The power amplifier includes a power amplifier input, with the power amplifier coupled between the driver amplifier output and the output port. The Darlington circuit is coupled to the driver amplifier via a node that is coupled between the input port and the power amplifier input.

In an example aspect, an apparatus for clamping a voltage with regard to at least a driver amplifier is disclosed. The apparatus includes an amplifier circuit having an input port and an output port. The amplifier circuit includes a driver amplifier having a driver amplifier input, a driver amplifier output, and means for amplifying a signal. The driver amplifier is coupled to the input port via the driver amplifier input. The amplifier circuit also includes a power amplifier having a power amplifier input and a power amplifier output. The power amplifier is coupled to the driver amplifier output via the power amplifier input and to the output port via the power amplifier output. The amplifier circuit further includes means for clamping a supply voltage of the means for amplifying a signal.

In an example aspect, a method for clamping power by a Darlington circuit with respect to an amplifier circuit or for operating a power clamp having a Darlington circuit is disclosed. The method includes accepting a signal at a signal input of an integrated circuit die and accepting a supply voltage at a power input of the integrated circuit die. The method also includes amplifying, using a driver amplifier and the supply voltage, the signal to produce a first amplified signal. The method additionally includes amplifying, using a power amplifier, an intermediate signal to produce a second amplified signal, the intermediate signal at least based on the first amplified signal. The method further includes clamping the supply voltage using two or more transistors that are coupled together in a Darlington transistor arrangement.

### BRIEF DESCRIPTION OF DRAWINGS

FIG. 1 illustrates an environment with an example electronic device that has a wireless interface device, which includes at least one example amplifier circuit with a Darlington circuit.

FIG. 2 is a schematic diagram illustrating an example radio-frequency (RF) front-end and an example transceiver that can each include at least one amplifier circuit with a Darlington circuit.

FIG. 3 is a schematic diagram illustrating an example amplifier die including an amplifier circuit, which includes a driver amplifier and a power amplifier, and a Darlington circuit coupled to the driver amplifier.

FIG. 4 is a circuit diagram illustrating an example Darlington circuit, which may be coupled to a driver amplifier of an amplifier circuit.

FIG. 5 is a circuit diagram illustrating an example amplifier circuit with a driver amplifier and a power amplifier and with multiple example nodes at which a Darlington circuit can be coupled.

FIG. 6 is a flow diagram illustrating an example process for clamping power by a Darlington circuit with respect to an amplifier circuit or for operating a power clamp having a Darlington circuit.

### DETAILED DESCRIPTION

### Introduction and Overview

To facilitate transmission and reception of wireless signals, an electronic device can use a wireless interface device that includes a wireless transceiver and/or a radio-frequency (RF) front-end. The wireless interface device includes various electrical and electronic components that operate based on voltages and currents and that process signals using such voltages and currents. These components are designed to operate within specified ranges of voltages and currents. If the operating conditions deviate from these specified ranges, the components may produce faulty signaling. Moreover, deviations from specified operating conditions can damage the components, especially if the operational current or voltage is higher than the corresponding specified range.

To protect components of a circuit, such as the transistors used for amplification or switching, a circuit can include a power clamp. A power clamp can prevent the power experienced by a component from exceeding the amount of power that damages the component. To do so, the power clamp can limit a voltage level or a current magnitude. This may include limiting voltage and current in accordance with a permitted, but optional, interpretation of the word “or” as encompassing an “inclusive or” relationship. In some cases, a power clamp can be used to provide, for example, over-voltage protection or electrostatic discharge (ESD) protection.

In certain wireless interface device environments, some control functionality is separated from at least a portion of amplifier functionality. For example, a controller die can be separate from an amplifier die. The controller die may be realized with complementary metal-oxide-semiconductor (CMOS) or silicon on insulator (SOI) process technology. The amplifier die includes an amplification circuit, which can include a driver amplifier and a power amplifier. The controller die can condition a signal, such as a radio-frequency signal (RF signal), prior to amplification by the power amplifier using, for instance, a filter or a pre-driver amplifier.

In one approach to protecting circuit components, an input clamp is deployed at the controller die to meet power protection specifications for the components of the controller die and the amplifier die. With the input clamp on the controller die, however, the RF input signal routing is relatively extensive. The RF input signal enters the controller die and propagates through multiple blocks or stages to condition the signal. These blocks can include an input attenuator, the input clamp, an input switch, a pre-driver amplifier, and so forth. The conditioned RF signal then exits from the controller die and travels to the amplifier die, which includes the power amplifier. This appreciable routing distance creates problems for the RF signal. First, the routing distance degrades the quality of the signal itself, such as by altering the phase of the signal. Second, the routing distance shifts a designed target power-clamping protection threshold to an actual power-clamping protection threshold that may be lower than the targeted one.

This leaves components of the amplifier die, including the power amplifier, vulnerable to damage from higher-than-specified voltages and currents. Accordingly, the power amplifier circuitry can be damaged, and the die can become useless. A die that is discovered to be useless during testing at a manufacturing facility results in financial loss. Further, a die that becomes damaged after being deployed in an electronic device causes still more harm as a whole electronic device, like a cell phone, may be rendered inoperable and returned by a customer.

To at least reduce this routing distance between an input power clamp and a power amplifier, this document describes other approaches to protecting circuit components in which a power clamp is incorporated into an integrated circuit chip having a driver amplifier or a power amplifier. This amplifier die can be realized using, for instance, gallium arsenide (GaAs) semiconductor technology. The power clamp can be coupled to a node of an amplifier circuit of the amplifier die. In some cases, the amplifier circuit includes a driver amplifier that feeds a power amplifier. The node may be associated with the driver amplifier. For example, the node may correspond to a power distribution node for a transistor of the driver amplifier or to a channel terminal of the transistor of the driver amplifier.

In some implementations, the power clamp can be realized with a Darlington circuit. The Darlington circuit includes two or more transistors coupled together in a Darlington arrangement between the node associated with the driver amplifier and another node, such as another power distribution node. The Darlington circuit can also include multiple diodes coupled together in series. A quantity of the multiple series-connected diodes can establish, at least partly, a trigger point for the power clamp. The Darlington circuit can limit a voltage level at the node or a current magnitude flowing through the node to the transistor of the driver amplifier based on the trigger point. The Darlington circuit can further include one or more other diodes coupled together in series in an opposite direction to protect against opposite voltages.

Thus, certain described implementations include an input power clamp that is disposed on a same die as a power amplifier, which is part of an amplification circuit. The power clamp can be realized with a Darlington circuit or can be coupled to a driver amplifier of the amplification circuit. The Darlington circuit of the power clamp can provide ESD protection on the driver stage amplifier. The Darlington circuit can further operate as the voltage or current clamping of the driver stage amplifier. This clamping at the driver amplifier can therefore limit the input power to the power amplifier, which “follows” the driver amplifier from a signal flow or signal processing perspective.

The on-die power clamping approach as described herein provides an appreciably shorter routing distance between the power clamp and the power amplifier along the RF signal chain. This shorter routing distance is achieved without appreciably increasing the size of the amplifier die. Accordingly, a targeted power clamping protection threshold can be achieved at the power amplifier with more certainty and with less signal degradation. Further, overall product cost is reduced by omitting or removing the power clamp from the controller die.

A Darlington circuit can therefore be coupled to a driver amplifier stage cell (e.g., via a collector terminal of a heterojunction bipolar transistor (HBT) or a drain terminal of a field-effect transistor (FET)) to provide an input clamping function. Example implementations of the Darlington-circuit-based power clamp can provide power clamping capability for an input of the power amplifier via the driver amplifier. Further, a stronger clamping effect can be enforced or implemented as a power supply voltage (e.g., Vcc) increases, which provides superior protection. In comparison to the controller-die approach presented above, the amplifier-die approach with a Darlington circuit can also provide superior ESD ratings, at least in accordance with the human body model (HBM) of ESD protection. Additional example implementations for employing a Darlington circuit with a driver amplifier to provide power clamping protection are described herein.

### Description Examples

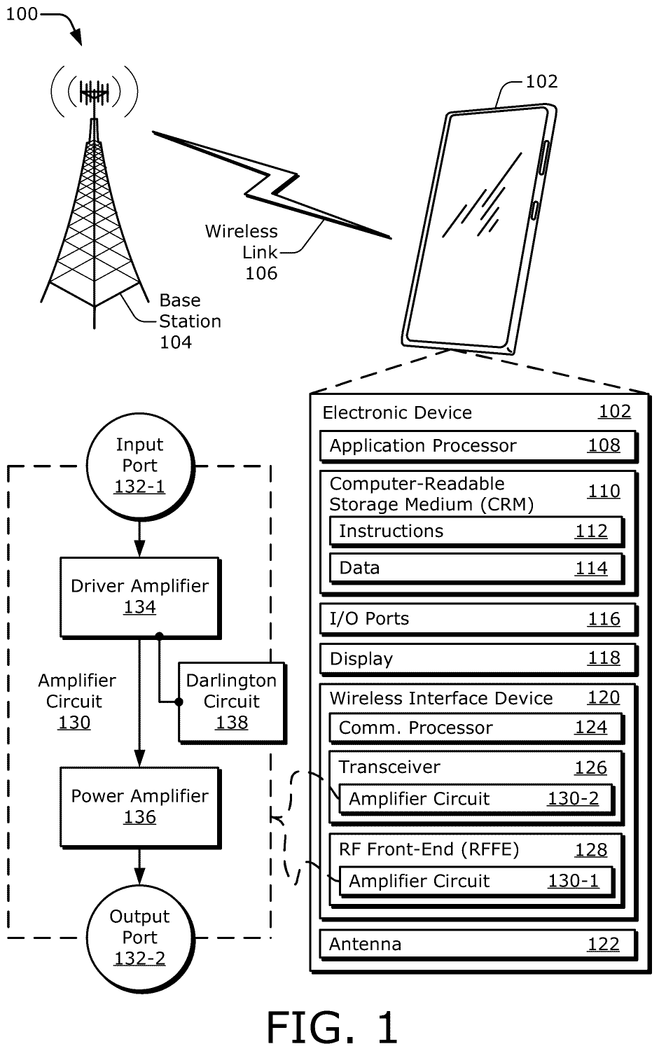

FIG. 1 illustrates an example environment 100 with an electronic device 102 that has a wireless interface device 120, which includes at least one example amplifier circuit 130 with a Darlington circuit 138. This document describes example implementations of the amplifier circuit 130, which may be part of a transceiver, a radio-frequency front-end (RFFE), and so forth of an apparatus. In the environment 100, the example electronic device 102 communicates with a base station 104 through a wireless link 106.

In FIG. 1, the electronic device 102 is depicted as a smartphone. The electronic device 102, however, may be implemented as any suitable computing or other electronic device. Examples of an apparatus that can be realized as an electronic device 102 include a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, fitness management device, wearable device such as intelligent glasses or smartwatch, wireless power device (transmitter or receiver), medical device, and so forth.

The base station 104 communicates with the electronic device 102 via the wireless link 106, which may be implemented as any suitable type of wireless link that carries a communication signal. Although depicted as a base station tower of a cellular radio network, the base station 104 may represent or be implemented as another device, such as a satellite, terrestrial broadcast tower, access point, peer-to-peer device, mesh network node, fiber optic line interface, another electronic device as described above generally, and so forth. Hence, the wireless link 106, or an extension thereof, can connect between the electronic device 102 and the base station 104 in any of various manners.

The wireless link 106 can include a downlink of data or control information communicated from the base station 104 to the electronic device 102. The wireless link 106 can also include an uplink of other data or control information communicated from the electronic device 102 to the base station 104. The wireless link 106 may be implemented using any suitable wireless communication protocol or standard. Examples of such protocols and standards include a 3^{rd} Generation Partnership Project (3GPP) Long-Term Evolution (LTE) standard, such as a 4^{th} Generation (4G), a 5^{th} Generation (5G), or a 6^{th} Generation (6G) cellular standard; an IEEE 802.11 standard, such as 802.11g, ac, ax, ad, aj, or ay standard (e.g., Wi-Fi® 6 or WiGig®); an IEEE 802.16 standard (e.g., WiMAX®); a Bluetooth® standard; an ultra-wideband (UWB) standard (e.g., IEEE 802.15.4); and so forth. In some implementations, the wireless link 106 may provide power wirelessly, and the electronic device 102 or the base station 104 may comprise a power source.

As shown for some implementations, the electronic device 102 can include at least one application processor 108 and at least one computer-readable storage medium 110 (CRM 110). The application processor 108 may include any type of processor, such as a central processing unit (CPU) or a multi-core processor, that is configured to execute processor-executable instructions (e.g., code) stored by the CRM 110. The CRM 110 may include any suitable type of data storage media, such as volatile memory (e.g., random-access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include one or more input/output ports 116 (I/O ports 116) and at least one display 118. The I/O ports 116 enable data exchanges or interaction with other devices, networks, or users. The I/O ports 116 may include serial ports (e.g., universal serial bus (USB®) ports), parallel ports, ethernet ports, audio ports, infrared (IR) ports, cameras or other sensor ports, and so forth. The display 118 can be realized as a display screen or a projection that presents graphical images provided by other components of the electronic device 102, such as a user interface (UI) associated with an operating system, program, or application. Alternatively or additionally, the display 118 may be implemented as a display port or virtual interface through which graphical content of the electronic device 102 is communicated or presented.

The electronic device 102 further includes at least one wireless interface device 120 and at least one antenna 122. The example wireless interface device 120 provides connectivity to respective networks and peer devices via a wireless link, which may be configured similarly to or differently from the wireless link 106. The wireless interface device 120 may facilitate communication over any suitable type of wireless network, such as a wireless local area network (LAN) (WLAN), wireless personal-area-network (PAN) (WPAN), peer-to-peer (P2P) network, mesh network, cellular network, wireless wide-area-network (WAN) (WWAN), and/or navigational network (e.g., the Global Positioning System (GPS) of North America or another Satellite Positioning System (SPS) or Global Navigation Satellite System (GNSS)). In the context of the example environment 100, the electronic device 102 can communicate various data and control information bidirectionally with the base station 104 via the wireless interface device 120. The electronic device 102 may, however, communicate directly with other peer devices, an alternative wireless network, and the like. Also, as described above, an electronic device 102 may alternatively be implemented as a base station 104 or another apparatus as set forth herein.

As shown, the wireless interface device 120 can include at least one communication processor 124, at least one transceiver 126 (e.g., a wireless transceiver 126), and at least one radio-frequency front-end 128 (RFFE 128). These components process data information, control information, and signals associated with communicating information for the electronic device 102 via the antenna 122. The communication processor 124 may be implemented as at least part of a system-on-chip (SoC), as a modem processor, or as a baseband radio processor (BBP) that enables a digital communication interface for data, voice, messaging, or other applications of the electronic device 102. The communication processor 124 can include a digital signal processor (DSP) or one or more signal-processing blocks (not shown) for encoding and modulating data for transmission and for demodulating and decoding received data. Additionally, the communication processor 124 may also manage (e.g., control or configure) aspects or operation of the transceiver 126, the RF front-end 128, and other components of the wireless interface device 120 to implement various communication protocols or communication techniques.

In some cases, the application processor 108 and the communication processor 124 can be combined into one module or integrated circuit (IC), such as an SoC. Regardless, the application processor 108, the communication processor 124, or a processor generally can be operatively coupled to one or more other components, such as the CRM 110 or the display 118, to enable control of, or other interaction with, the various components of the electronic device 102. For example, at least one processor 108 or 124 can present one or more graphical images on a display screen implementation of the display 118 based on one or more wireless signals transmitted or received via the at least one antenna 122 using components of the wireless interface device 120. Further, the application processor 108 or the communication processor 124, including a combination thereof, can be realized using digital circuitry that implements logic or functionality that is described herein. Additionally, the communication processor 124 may also include or be associated with a memory (not separately depicted) to store data and processor-executable instructions (e.g., code), such as the same or another CRM 110.

As shown, the wireless interface device 120 can include at least one amplifier circuit 130 (or amplification circuit 130), which is described below. More specifically, the transceiver 126 can include at least one amplifier circuit 130-2, or the RF front-end 128 can include at least one amplifier circuit 130-1 (including both components can have at least one amplifier circuit 130 in accordance with an optional but permitted inclusive-or interpretation of the word “or”). The transceiver 126 can also include circuitry and logic for filtering, switching, amplification, channelization, frequency translation, and so forth. Frequency translation functionality may include an up-conversion or a down-conversion of frequency that is performed through a single conversion operation (e.g., with a direct-conversion architecture) or through multiple conversion operations (e.g., with a superheterodyne architecture). Generally, the transceiver 126 can include filters, switches, amplifiers, mixers, and so forth for routing and conditioning signals that are transmitted or received via the antenna 122.

In addition to the amplifier circuit 130-2, the transceiver 126 can include an analog-to-digital converter (ADC) or a digital-to-analog converter (DAC) (not shown in FIG. 1). In operation, an ADC can convert analog signals to digital signals, and a DAC can convert digital signals to analog signals. Generally, an ADC or a DAC can be implemented as part of the communication processor 124, as part of the transceiver 126, or separately from both (e.g., as another part of an SoC or as part of the application processor 108).

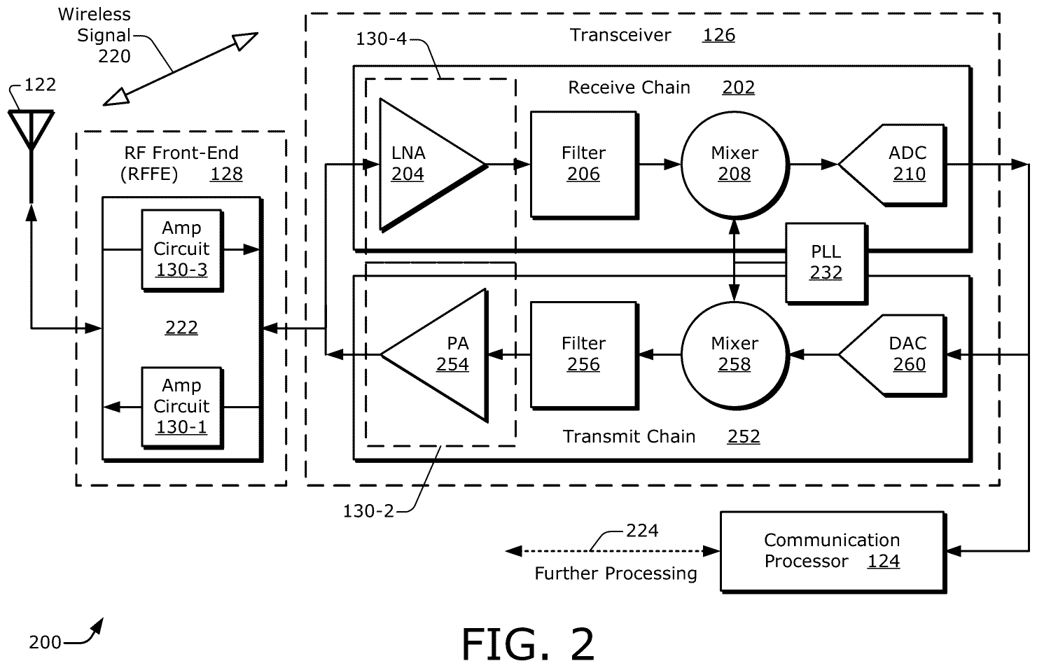

The components or circuitry of the transceiver 126 can be implemented in any suitable fashion, such as with combined transceiver logic or separately as respective transmitter and receiver entities. In some cases, the transceiver 126 is implemented with multiple or different sections to implement respective transmitting and receiving operations (e.g., with separate transmit and receive chains as depicted in FIG. 2). Although not shown in FIG. 1, the transceiver 126 may also include logic to perform in-phase/quadrature (I/Q) operations, such as synthesis, phase correction, modulation, demodulation, and the like.

The RF front-end 128 can include one or more filters, multiple switches, or one or more amplifiers-such as the amplifier circuit 130-1—for conditioning signals received via the antenna 122 or for conditioning signals to be transmitted via the antenna 122. The RF front-end 128 may also include a phase shifter (PS), peak detector, power meter, gain control block, antenna tuning circuit, n-plexer, balun, and the like. Configurable components of the RF front-end 128, such as some phase shifters, an automatic gain controller (AGC), or a switch, may be controlled by the communication processor 124 to implement communications in various modes, communications with different frequency bands and/or carrier aggregation (CA), or communications using beamforming.

In some implementations, the antenna 122 is implemented as at least one antenna array that includes multiple antenna elements. Thus, as used herein, an “antenna” can refer to at least one discrete or independent antenna, to at least one antenna array that includes multiple antenna elements, or to a portion of an antenna array (e.g., an antenna element), depending on context or implementation. At least one antenna 122 may also be part of a module that includes one or more other components (e.g., an amplifier circuit 130-1 or a filter) of the RF front-end 128, or the at least one antenna 122 may be a separate component.

In FIG. 1, an example amplifier circuit 130 is depicted as being part of a transceiver 126 as amplifier circuit 130-2, as being part of an RF front-end 128 as amplifier circuit 130-1, and so forth. Described implementations of an amplifier circuit 130 can, however, additionally or alternatively be employed in other portions of the wireless interface device 120 or in other portions of the electronic device 102 generally. As set forth above, an amplifier circuit 130 can be included in an electronic device other than a cell phone, such as a base station 104. With a base station (or a mobile phone), by way of example only, a transmit or receive chain, e.g., of an intermediate-frequency (IF) section, of a wireless interface device 120 and/or an RF front-end 128 may include an amplifier circuit 130 as described herein. Other electronic device apparatuses that can employ an amplifier circuit 130 include a laptop, communication hardware of a vehicle, a wireless access point, and so forth as described herein.

In example implementations, the amplifier circuit 130 can include at least one port 132, such as an input port 132-1 and an output port 132-2 (or, more generally, a first port 132-1 and a second port 132-2). As illustrated, the amplifier circuit 130 can include at least one driver amplifier 134, at least one power amplifier 136, and at least one Darlington circuit 138. In some cases, the driver amplifier 134 and the power amplifier 136 are coupled in series between the input port 132-1 and the output port 132-2. As shown, the driver amplifier 134 can be coupled closer to the input port 132-1 than the power amplifier 136, and the power amplifier 136 can be coupled closer to the output port 132-2 than the driver amplifier 134. Thus, the driver amplifier 134 can be coupled between the input port 132-1 and the power amplifier 136, and the power amplifier 136 can be coupled between the driver amplifier 134 and the output port 132-2. The Darlington circuit 138 may be coupled to the driver amplifier 134 to provide power clamping functionality for one or more parts, cells, or stages of the amplifier circuit 130.

As depicted, signal flow can proceed from the input port 132-1 to and through the driver amplifier 134. From the driver amplifier 134, a first amplified signal can propagate to and through the power amplifier 136. A second amplified signal that is output from the power amplifier 136 can travel to the output port 132-2. Two amplifiers of the amplifier circuit 130 are described herein primarily in terms of a driver amplifier 134 and a power amplifier 136. However, two or more amplifiers that are protected by a Darlington circuit 138 may be generally referred to as first amplifier and a second amplifier. Such other amplifiers may be or include any type of amplifier that is employed for any purpose, such as low-noise amplifier, an operational amplifier, any given class of amplifier, a combination thereof, and so forth.

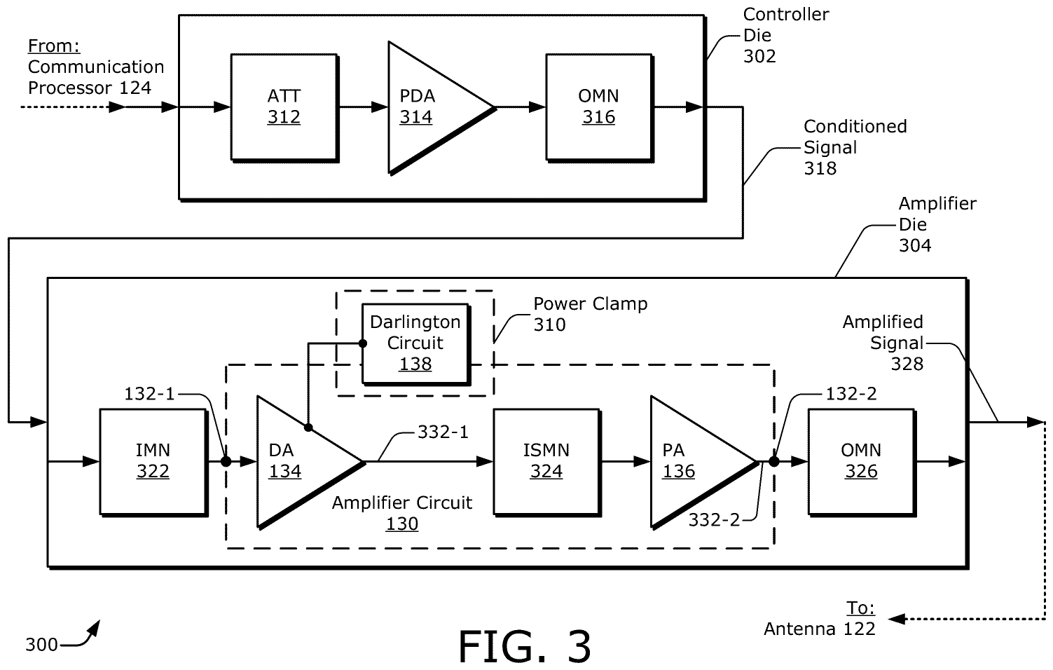

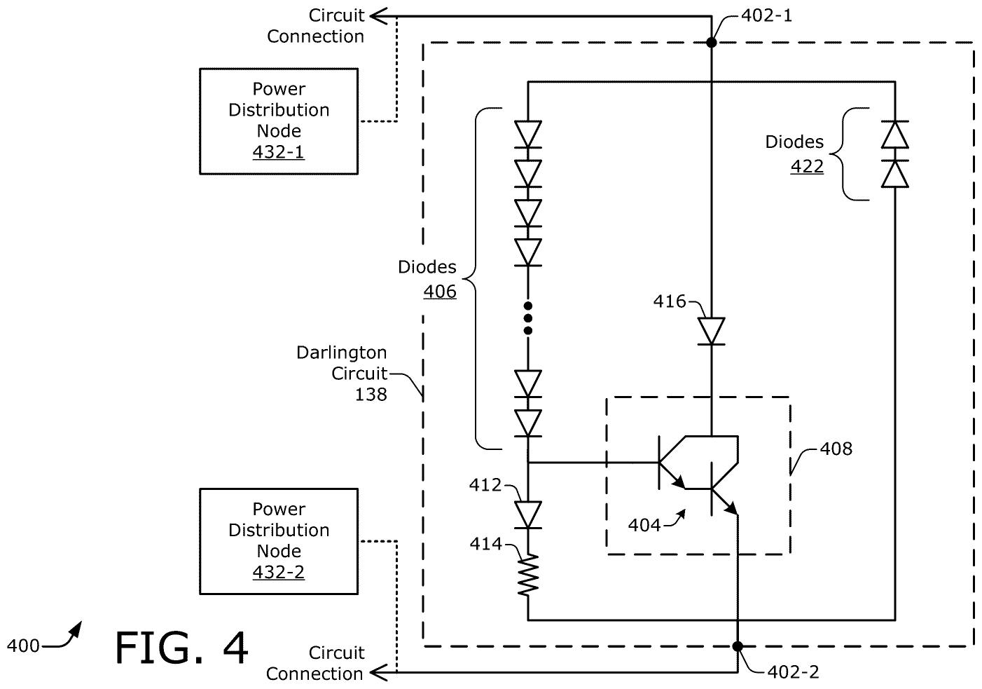

Although a particular quantity and arrangement of components are explicitly depicted in FIG. 1 (and in FIGS. 2 to 5), an amplifier circuit 130 may include more or fewer of any of such components, as well as other components that are not shown. Further, the components may be arranged and interconnected in different manners. Example implementations of a Darlington circuit 138 and at least one node to which it is coupled are described below with reference to multiple figures, starting with FIGS. 3 and 4. Next, however, this document describes example implementations of a transceiver and an RF front-end with reference to FIG. 2.

FIG. 2 is a schematic diagram 200 illustrating an example RF front-end 128 and an example transceiver 126 that can each include at least one amplifier circuit 130 with a Darlington circuit 138 (not shown in FIG. 2). FIG. 2 also depicts an antenna 122 and a communication processor 124. The communication processor 124 communicates one or more data signals to other components, such as the application processor 108 of FIG. 1, for further processing at 224 (e.g., for processing at an application level). As shown, the circuitry 200 can include a first amplifier circuit 130-1, a second amplifier circuit 130-2, a third amplifier circuit 130-3, or a fourth amplifier circuit 130-4, including one to four of such amplifier circuits. The circuitry 200, however, may include a different quantity of amplifiers (e.g., more or fewer amplifier circuits), may include amplifiers or other components that are coupled together differently, may include amplifiers in different locations, may include amplifiers that are implemented with two or more stages, some combination thereof, and so forth.

As illustrated from left to right, in example implementations, the antenna 122 is coupled to the RF front-end 128, and the RF front-end 128 is coupled to the transceiver 126. The transceiver 126 is coupled to the communication processor 124. The example RF front-end 128 includes at least one signal propagation path 222. The at least one signal propagation path 222 can include at least one amplifier circuit 130, such as the amplifier circuit 130-1 and the amplifier circuit 130-3. The example wireless transceiver 126 includes at least one receive chain 202 (or receive path 202) and at least one transmit chain 252 (or transmit path 252). Although only one RF front-end 128, one transceiver 126, and one communication processor 124 are shown at the circuitry 200, an electronic device 102, or a wireless interface device 120 thereof, can include multiple instances of any or all such components. Also, although only certain components are explicitly depicted in FIG. 2 and are shown coupled together in a particular manner, the transceiver 126 or the RF front-end 128 may include other non-illustrated components (e.g., switches or buffers), more or fewer components, differently coupled arrangements of components, and so forth.

In some implementations, the RF front-end 128 couples the antenna 122 to the transceiver 126 via the signal propagation path 222. In operation, the signal propagation path 222 carries a signal between the antenna 122 and the transceiver 126. During or as part of the signal propagation, the signal propagation path 222 conditions the propagating signal, such as with the amplifier circuit 130-1 or the amplifier circuit 130-3. This enables the RF front-end 128 to couple a wireless signal 220 from the antenna 122 to the transceiver 126 as part of a reception operation. The RF front-end 128 also enables a transmission signal to be coupled from the transceiver 126 to the antenna 122 as part of a transmission operation to emanate a wireless signal 220. Although not explicitly shown in FIG. 2, an RF front-end 128, or a signal propagation path 222 thereof, may include one or more other components, such as another amplifier (e.g., a driver amplifier, a power amplifier, or a low-noise amplifier), a filter, an n-plexer, a phase shifter, a diplexer, one or more switches, and so forth.

In some implementations, the transceiver 126 can include at least one receive chain 202, at least one transmit chain 252, or at least one receive chain 202 and at least one transmit chain 252. From left to right, the receive chain 202 can include a low-noise amplifier 204 (LNA 204), a filter 206, a mixer 208 for frequency down conversion, and an ADC 210. The transmit chain 252 can include a power amplifier 254 (PA 254), a filter 256, a mixer 258 for frequency up-conversion, and a DAC 260. However, the receive chain 202 or the transmit chain 252 can include other components—for example, additional amplifiers or filters, multiple mixers, one or more buffers, or at least one local oscillator—that are electrically or electromagnetically disposed anywhere along the depicted receive and transmit chains.

The receive chain 202 is coupled between the signal propagation path 222 of the RF front-end 128 and the communication processor 124—e.g., via the low-noise amplifier 204 and the ADC 210, respectively. The transmit chain 252 is coupled between the signal propagation path 222 and the communication processor 124—e.g., via the power amplifier 254 and the DAC 260, respectively. The transceiver 126 can also include at least one phase-locked loop 232 (PLL 232) that is coupled to the mixer 208 or the mixer 258. For example, the transceiver 126 can include one PLL 232 for each transmit/receive chain pair, one PLL 232 per transmit chain and one PLL 232 per receive chain, multiple PLLs 232 per chain, and so forth.

As shown along a signal propagation direction for certain example implementations of the receive chain 202, the antenna 122 is coupled to the low noise amplifier 204 via the signal propagation path 222 and the amplifier circuit 130-3 thereof. The low-noise amplifier 204 is coupled to the filter 206. The filter 206 is coupled to the mixer 208, and the mixer 208 is coupled to the ADC 210. The ADC 210 is in turn coupled to the communication processor 124. As shown along a signal propagation direction for certain example implementations of the transmit chain 252, the communication processor 124 is coupled to the DAC 260, and the DAC 260 is coupled to the mixer 258. The mixer 258 is coupled to the filter 256, and the filter 256 is coupled to the power amplifier 254. The power amplifier 254 is coupled to the antenna 122 via the signal propagation path 222 using the amplifier circuit 130-1 thereof. Although only one receive chain 202 and one transmit chain 252 are explicitly shown, an electronic device 102, or a transceiver 126 thereof, can include multiple instances of either or both components. Although the ADC 210 and the DAC 260 are illustrated as being separately coupled to the communication processor 124, they may share a bus or other mechanism for communicating with the processor 124. Further, the ADC 210 or the DAC 260 may be part of the communication processor 124 or separate from the transceiver 126 and the communication processor 124.

As part of an example signal-receiving operation, the amplifier circuit 130-3 of the signal propagation path 222 amplifies a received signal and forwards the amplified signal to the low-noise amplifier 204. The low-noise amplifier 204 accepts the amplified signal from the RF front-end 128 and provides another amplified signal to the filter 206 based on the accepted signal. The filter 206 filters the other amplified signal and provides a filtered signal to the mixer 208. The mixer 208 performs a frequency conversion operation on the filtered signal to down-convert from one frequency to a lower frequency (e.g., from a radio frequency (RF) to an intermediate frequency (IF) or from RF or IF to a baseband frequency (BBF)). The mixer 208 can perform the frequency down-conversion in a single conversion step or through multiple conversion steps using at least one PLL 232. The mixer 208 can provide a down-converted signal to the ADC 210 for conversion and forwarding to the communication processor 124 as a digital signal.

As part of an example signal-transmitting operation, the mixer 258 accepts an analog signal at BBF from the DAC 260 (or accepts an analog IF signal if the signal has already been upconverted once by another mixer (not shown)). The mixer 258 upconverts the analog signal to a higher frequency, such as to an RF frequency, to produce an RF signal using a signal generated by the PLL 232 to have a target synthesized frequency. The mixer 258 provides the RF or other upconverted signal to the filter 256. The filter 256 filters the RF signal and provides a filtered signal to the power amplifier 254. Thus, after the filtering by the filter 256, the power amplifier 254 amplifies the filtered signal and provides an amplified signal to the signal propagation path 222 for signal conditioning. The RF front-end 128 can use, for instance, the amplifier circuit 130-1 of the signal propagation path 222 to provide a further amplified signal to the antenna 122 for emanation as a wireless signal 220.

Example implementations of an amplifier circuit 130, as described herein, may be employed at any one or more of the example amplifier circuits 130-1, 130-2, 130-3, or 130-4 in the transceiver 126 or the RF front-end 128 or at other amplifiers of an electronic device 102 (not shown in FIG. 2). In some cases, if the first amplifier circuit 130-1 of the RF front-end 128 includes a driver amplifier 134 and a power amplifier 136 (e.g., of FIGS. 1 and 3), the transceiver 126 may omit a power amplifier 254 or “substitute” a driver amplifier or a pre-driver amplifier therefor. Additionally or alternatively, the second amplifier circuit 130-2 may include a driver amplifier and a Darlington circuit 138 (neither of which is shown in FIG. 2) in conjunction with the depicted power amplifier 254.

In some cases, the third amplifier circuit 130-3 of the RF front-end 128 includes two or more amplifiers in conjunction with a Darlington circuit 138. At least one of these two or more amplifiers may be realized as a low-noise amplifier for receive signal processing. Additionally or alternatively, the fourth amplifier circuit 130-4 may include a driver amplifier and a Darlington circuit 138 (neither of which is shown in FIG. 2) in conjunction with the depicted low-noise amplifier 204. Further, the fourth amplifier circuit 130-4 may instead include multiple low-noise amplifiers in conjunction with a Darlington circuit 138 that provides a clamping function. Generally, an amplifier circuit 130 with a Darlington circuit 138 can be deployed anywhere in a transceiver 126, an RF front-end 128, another portion of a wireless interface device 120, or another part of an electronic device 102.

The circuitry 200, however, depicts just some examples for a transceiver 126 and/or an RF front-end 128. In some cases, the various components that are illustrated in the drawings using separate schematic blocks or circuit elements may be manufactured or packaged in different discrete manners. For example, one physical module may include components of the RF front-end 128 and a portion of the components of the transceiver 126, and another physical module may combine the communication processor 124 with the remaining components of the transceiver 126. Further, in some cases, the antenna 122 may be co-packaged with at least some components of the RF front-end 128 (e.g., may be co-packaged with an amplifier circuit 130 and at least one filter) or with those of the transceiver 126. Although certain amplifiers in FIG. 2 are depicted as an amplifier circuit 130 that can include a Darlington circuit 138 (not shown in FIG. 2) as described herein, any one or more of such amplifier circuits may instead be implemented without a Darlington circuit 138 or as an amplifier circuit that clamps a voltage or a current in a different manner.

In additional or alternative implementations, one or more components may be physically or logically “shifted” to a different part of the wireless interface device 120 as compared to the illustrated circuitry 200 and/or may be incorporated into a different module. For example, a low-noise amplifier 204 or a power amplifier 254 may alternatively or additionally be deployed in the RF front-end 128, such as by being at least part of the amplifier circuit 130-3 or the amplifier circuit 130-1, respectively. Examples of an amplifier circuit 130-1 with a power amplifier 136 (or a power amplifier 254) are described next with reference to FIG. 3.

FIG. 3 is a schematic diagram 300 illustrating an example amplifier die 304 including an amplifier circuit 130, which includes a driver amplifier 134 and a power amplifier 136, and a Darlington circuit 138 coupled to the driver amplifier 134. As illustrated, the schematic diagram 300 includes a controller die 302 and the amplifier die 304. The controller die 302 and the amplifier die 304 can be coupled together in series between a communication processor 124 (e.g., of FIGS. 1 and 2) and an antenna 122 (e.g., of FIGS. 1 and 2). More generally, two separate dies or integrated circuit chips may be referred to as a first die and a second die.

In example operations, an input of the controller die 302 receives a signal from the communication processor 124. Although not shown in FIG. 3, other components (e.g., a mixer or a filter) may be coupled between the communication processor 124 and the input of the controller die 302. An output of the controller die 302 produces a conditioned signal 318, and the conditioned signal 318 is coupled to an input of the amplifier die 304. After amplification, the amplifier die 304 provides an amplified signal 328 at an output of the amplifier die 304. The amplified signal 328 can be forwarded to the antenna 122. Although not shown in FIG. 3, other components (e.g., a mode switch, a filter, or a front-end module (FEM)) can be coupled between the output of the amplifier die 304 and the antenna 122.

As shown, the controller die 302 includes at least one attenuator 312 (ATT 312), at least one pre-driver amplifier 314 (PDA 314), and at least one output-matching network 316 (OMN 316). The attenuator 312, the pre-driver amplifier 314, and the output-matching network 316 are coupled together in series between the input and the output of the controller die 302. The controller die 302 may, however, include more, fewer, or different components. The depicted components and other components may be arranged and coupled together similarly or differently from those that are depicted.

In one approach, a power clamp can be coupled between the attenuator 312 and the pre-driver amplifier 314. This power clamp can limit the power input to the downstream power amplifier 136. However, as described above, the relatively long signal path between the pre-driver amplifier 314 of the controller die 302 and the power amplifier 136 of the amplifier die 304 creates signaling problems. These problems include signal degradation and a failure to attain a targeted power clamping protection threshold at the power amplifier 136.

In example implementations, to ameliorate these problems at least partly, this document describes incorporating at the driver amplifier 134 on the amplifier die 304 a Darlington circuit 138 as at least part of a power clamp 310. The Darlington circuit 138 can provide power clamping for an integrated circuit die with respect to power that is supplied to the driver amplifier 134. The amplifier die 304 can include an input-matching network 322 (IMN 322), the amplifier circuit 130, and an output-matching network 326 (OMN 326). The input-matching network 322, the amplifier circuit 130, and the output-matching network 326 can be coupled together in series between an input and an output of the amplifier die 304.

As shown, the input-matching network 322 may be coupled between the input of the amplifier die 304 and the amplifier circuit 130 (e.g., via the input port 132-1). The output-matching network 326 may be coupled between the amplifier circuit 130 (e.g., via the output port 132-2) and the output of the amplifier die 304. Further, the amplifier circuit 130 may be coupled between the input-matching network 322 and the output-matching network 326. The amplifier die 304 may, however, include more, fewer, or different components. The depicted components and other components may be arranged and coupled together similarly or differently as compared to how the depicted ones are arranged and coupled together.

As illustrated, the amplifier circuit 130 includes the at least one driver amplifier 134, the at least one power amplifier 136, and at least one inter-stage matching network 324 (ISMN 324). In some cases, the driver amplifier 134, the inter-stage matching network 324, and the power amplifier 136 are coupled together in series between the input port 132-1 and the output port 132-2 of the amplifier circuit 130. As shown, the driver amplifier 134 can be coupled closer to the input port 132-1 than is the power amplifier 136, and the power amplifier 136 can be coupled closer to the output port 132-2 than is the driver amplifier 134. Thus, the driver amplifier 134 can be coupled between the input port 132-1 and the power amplifier 136, and the power amplifier 136 can be coupled between the driver amplifier 134 and the output port 132-2.

The inter-stage matching network 324 can be coupled between two stages: a first stage corresponding to the driver amplifier 134 and a second stage corresponding to the power amplifier 136. Accordingly, the driver amplifier 134 can be coupled between the input port 132-1 and the inter-stage matching network 324. The power amplifier 136 can be coupled between the inter-stage matching network 324 and the output port 132-2.

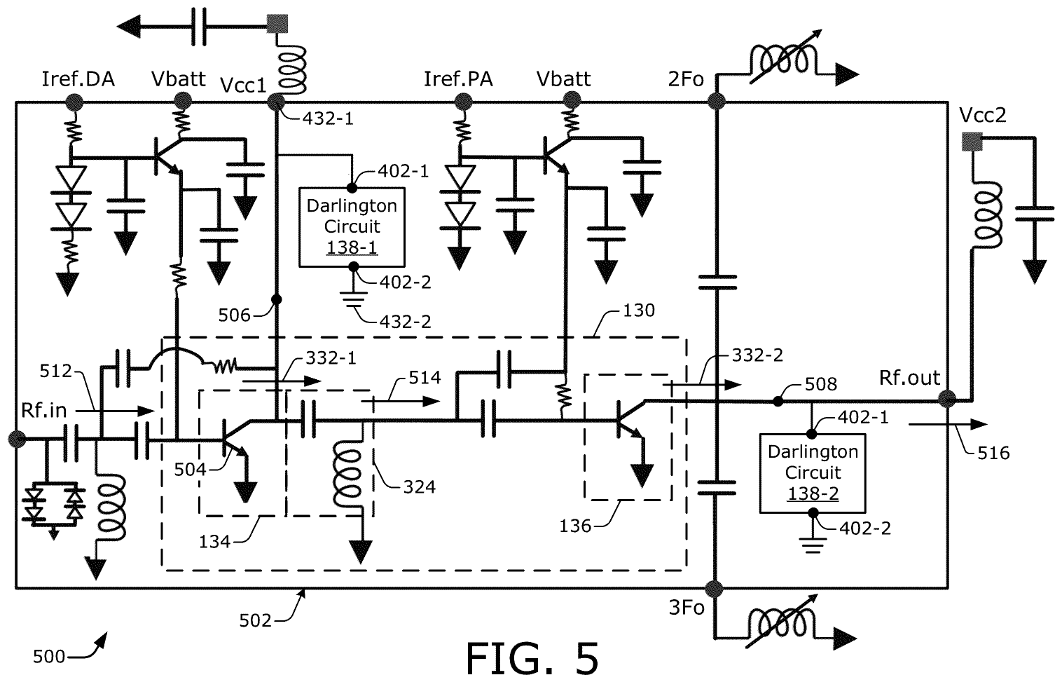

The Darlington circuit 138 may be coupled to the driver amplifier 134 to provide power clamping functionality for one or more parts, cells, stages, or components of the amplifier circuit 130. For instance, as at least part of the power clamp 310, the Darlington circuit 138 can provide power protection for downstream components, including for an input of the power amplifier 136. The Darlington circuit 138 can be coupled, for example, to a power distribution node that provides power to at least one transistor of the driver amplifier 134, to a terminal of at least one transistor of the driver amplifier 134, some combination thereof, and so forth. Example couplings between the Darlington circuit 138 and the driver amplifier 134 are described below with reference to FIGS. 4 and 5.

As depicted, signal flow can proceed from the input port 132-1 to and through the driver amplifier 134. The driver amplifier 134 produces a first amplified signal 332-1. From the driver amplifier 134, the first amplified signal 332-1 can propagate through the inter-stage matching network 324 and to the power amplifier 136, which produces a second amplified signal 332-2. The second amplified signal 332-2 that is output from the power amplifier 136 can travel to the output port 132-2 and the output-matching network 326.

Two amplifiers of the amplifier circuit 130 are described herein primarily in terms of a driver amplifier 134 and a power amplifier 136. However, two or more amplifiers that are protected by a Darlington circuit 138 may be generally referred to as first amplifier and a second amplifier. Such other amplifiers may be or may include any type of amplifier that is employed for any purpose, such as low-noise amplifier, an operational amplifier, an amplifier of any given class, a combination thereof, and so forth.

FIG. 4 is a circuit diagram 400 illustrating an example Darlington circuit 138, which may be coupled to a driver amplifier 134 of an amplifier circuit 130 (e.g., both of FIGS. 1 and 3). The Darlington circuit 138 includes at least two nodes that can be used to couple the Darlington circuit 138 to a larger circuit, such as via a driver amplifier 134. These at least two nodes include a first node 402-1 and a second node 402-2. Example circuit connections are described below with reference to FIG. 4 and further with reference to FIG. 5.

In example implementations, the Darlington circuit 138 includes two or more transistors 404 that are coupled together in a Darlington transistor arrangement or Darlington configuration 408. For instance, a channel terminal of a first transistor (e.g., on the left, as depicted in FIG. 4) may be coupled to a control terminal of a second transistor (e.g., on the right, as depicted in FIG. 4). Further, another channel terminal of the first transistor may be coupled to a channel terminal of the second transistor. A set of transistors that are coupled together in a Darlington transistor arrangement may have two transistors (e.g., a Darlington pair) as shown or may have more than two transistors. Generally, a Darlington configuration 408 for multiple transistors enables a first current that is amplified by the first transistor to be again amplified as a second current by the second transistor. The total current gain can therefore be greater than the current gain of any individual transistor.

Multiple transistors are described herein and depicted in the associated figures, which figures are incorporated by reference herein. These transistors may be realized in different manners or as different transistor types. Example transistor types include a field effect transistor (FET), a junction FET (JFET), a metal-oxide-semiconductor FET (MOSFET), a bipolar junction transistor (BJT), an insulated-gate bipolar transistor (IGBT), a heterojunction bipolar transistor (HBT), a combination thereof, and so forth. Manufacturers may fabricate FETs as n-channel or p-channel transistor types and may fabricate BJTs as NPN or PNP transistor types. The heterojunction bipolar transistor (HBT) can be considered a form or subset of the bipolar junction transistor (BJT). Although certain transistors are depicted in the figures as HBTs, one or more of these transistors may be implemented as a different transistor type.

Each transistor may include at least one control terminal and one or more channel terminals. With an FET, a control terminal can correspond to a gate terminal, and a channel terminal can correspond to a source terminal or a drain terminal. With a BJT (including an HBT), a control terminal can correspond to a base terminal, and a channel terminal can correspond to an emitter terminal or a collector terminal.

In a Darlington configuration 408, an emitter terminal (or source terminal) of the first transistor can be coupled to a base terminal (or gate terminal) of the second transistor. The base terminal (or gate terminal) of the first transistor acts as the base terminal (or gate terminal) of the Darlington transistor arrangement and may function as the input. The emitter terminal (or source terminal) of the second transistor acts as the emitter terminal (or source terminal) of the Darlington transistor arrangement and may provide an output current.

With continuing reference to FIG. 4, two or more diodes 406 can be coupled together in series between the first node 402-1 and the base terminal (or gate terminal) of the Darlington configuration 408 of the two or more transistors 404. A quantity of diodes of these two or more diodes 406 can set, at least in part, a voltage level that triggers protection by the Darlington circuit 138. For example, a voltage drop that turns on each diode, which can be dependent on material or process technology, multiplied by the quantity of diodes establishes a voltage level to turn on the two or more transistors 404 of the Darlington configuration 408. Thus, a power clamp 310 (e.g., of FIG. 3) that is implemented using a Darlington circuit 138 as described herein can be designed for different power levels. This may be achieved, at least in part, by deploying different quantities of triggering diodes for the two or more diodes 406 to establish a clamping voltage that is implemented by the Darlington circuit 138.

At least one diode 412 and at least one resistor 414 are shown coupled in series between the base terminal (or gate terminal) of the Darlington configuration 408 and the second node 402-2. A resistive value of the resistor 414 can also set, at least partly, a trigger voltage at which clamping protection starts. Generally, as the resistive value of the resistor 414 increases, the trigger voltage at which clamping is initiated decreases. Another diode 416 is shown coupled between the first node 402-1 of the Darlington circuit 138 and a terminal of the Darlington configuration 408, such as a collector terminal (or drain terminal) of the Darlington configuration 408. The diode 416, for instance, may be omitted while maintaining satisfactory instantaneous performance by the Darlington circuit 138. However, the presence of the diode 416 can keep the voltage swing lower on the Darlington transistor arrangement, which protects the Darlington configuration 408 and can extend its operational life.

One or more diodes 422 are shown coupled together in series between the first node 402-1 and the second node 402-2. These one or more diodes 422, however, are coupled in an opposite direction as compared to those diodes of the two or more diodes 406. These diodes of the one or more diodes 422 can therefore provide protection for voltages of an opposite sign (e.g., provide protection against negative voltages if the first node 402-1 is coupled to a positive supply voltage).

The diodes 422, like the other components depicted as being part of the Darlington circuit 138 (besides the at least two transistors 404), may be omitted from the Darlington circuit 138 or may be coupled to the Darlington configuration 408 while being separate from the Darlington circuit 138. Further, certain components are depicted or described as having a particular quantity, such as one, two, three, multiple, plural, singular, and so forth. Each of these components may, however, have a different quantity. By way of example only, the series-connected string of diodes 406 may instead be implemented with a single diode.

In some aspects, the Darlington circuit 138 may be coupled between two power distribution nodes. For example, the first node 402-1 may be coupled to a first power distribution node 432-1, and the second node 402-2 may be coupled to a second power distribution node 432-2. Examples of a power distribution node 432 include a supply voltage node (e.g., positive or negative Vcc) and a ground. In some cases, the first power distribution node 432-1 may be realized as a supply voltage node, and the second power distribution node 432-2 may be realized as a ground. In at least some of such cases, an associated driver amplifier 134 may also be powered by the first power distribution node 432-1. Example instances of this circuitry are described next with reference to FIG. 5. The power distribution node types (e.g., supply voltage node versus ground) may, however, be swapped, such as if the transistor or diode dopings are swapped or if the directions in which these components are coupled are swapped.

FIG. 5 is a circuit diagram 500 illustrating an example amplifier circuit 130 with a driver amplifier 134 and a power amplifier 136 and with multiple example nodes at which a Darlington circuit 138 can be coupled. FIG. 5 depicts an integrated circuit die 502 that includes multiple inputs or outputs that may be realized with a pin, pad, or other electrical contact node to couple signaling to or from the integrated circuit die 502. Examples of such input and outputs that are depicted in FIG. 5 include Rf.in, Rf.out, Vcc1, Vcc2, and so forth.

In example implementations, the driver amplifier 134 includes at least one transistor 504. A channel terminal of the transistor 504 (e.g., a collector terminal for a BJT or a drain terminal for an FET) is coupled to a node 506. The node 506 is coupled to the first power distribution node 432-1 and the first node 402-1 of the Darlington circuit 138-1. In some cases, the node 506 can correspond to the first power distribution node 432-1 or the first node 402-1 of the Darlington circuit 138-1, including can correspond to the first power distribution node 432-1 and the first node 402-1. The second node 402-2 is coupled to, and may correspond to, the second power distribution node 432-2. In the example of FIG. 5, the first power distribution node 432-1 is realized as a power supply voltage node (Vcc1), and the second power distribution node 432-2 is realized as the ground. The Darlington circuit 138 can clamp a voltage at the node 506 responsive to a voltage level that is based, at least partly, on a quantity of diodes of multiple diodes 406 of the Darlington circuit 138 (as shown in FIG. 4). Additionally or alternatively, the Darlington circuit 138 can increase a clamping action on a voltage at the node 506 as the voltage at the node increases.

In example operations, a control terminal of the transistor 504 (e.g., a base terminal of a BJT or a gate terminal of an FET) of the driver amplifier 134 receives an input signal 512. The driver amplifier 134 amplifies the input signal 512 to produce a first amplified signal 332-1. The inter-stage matching network 324 may modify the first amplified signal 332-1 to produce an intermediate signal 514, which is coupled to an input of the power amplifier 136. The power amplifier 136 amplifies the intermediate signal 514, which is at least based on the first amplified signal 332-1, to produce a second amplified signal 332-2. The second amplified signal 332-2 can be forwarded to the Rf.out output as an output signal 516 of the amplifier circuit 130 or the integrated circuit die 502.

The Darlington circuit 138-1 can be coupled to the driver amplifier 134 via the node 506 to provide power clamping. This power clamping can limit voltage or current at the driver amplifier 134. Further, this power clamping can limit an input power at the power amplifier 136. A Darlington circuit 138 as described herein can, however, be coupled to other nodes of the integrated circuit die 502 to provide other functionality.

By way of example, a Darlington circuit 138-2 is coupled to an output of the power amplifier 136 via a node 508. The Darlington circuit 138-2 can provide power clamping for a transistor of the power amplifier 136, for an output of the power amplifier 136, for an output of the integrated circuit 502, and so forth. The Darlington circuit 138-2 can be architected and operate similarly to the Darlington circuit 138 that is described above with reference to FIG. 4.

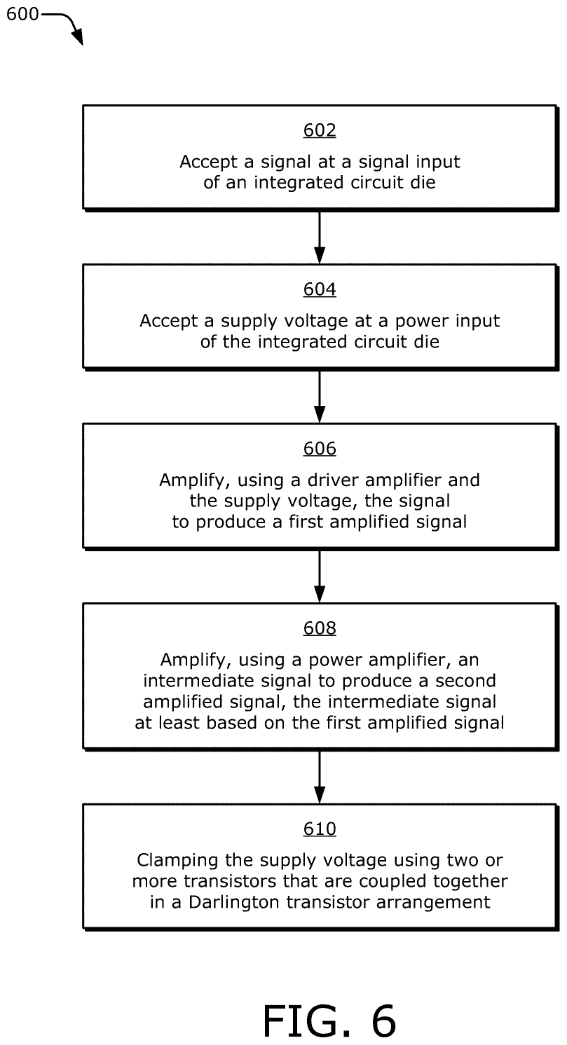

FIG. 6 is a flow diagram illustrating an example process 600 for clamping power by a Darlington circuit with respect to an amplifier circuit or for operating a power clamp having a Darlington circuit. The process 600 includes five blocks 602-610 that specify operations that can be performed for a method. However, operations are not necessarily limited to the order shown in the figures or described herein, for the operations may be implemented in alternative orders or in fully or partially overlapping manners. Also, more, fewer, and/or different operations may be implemented to perform a respective process or an alternative process.

In example implementations, operations represented by the illustrated blocks of each process may be performed by an electronic device, such as the electronic device 102 of FIG. 1 or the wireless interface device 120 thereof. More specifically, the operations of respective processes may be performed by an integrated circuit die (e.g., the amplifier die 304 of FIG. 3 or a die 502 of FIG. 5) and by an amplifier circuit 130 that includes a first amplifier and a second amplifier. Although some of the description herein focusses on amplifiers and power clamping that operate on single-ended signaling, the described principles (e.g., corresponding to devices, circuitry, techniques, and processes) are not so limited. Thus, these principles are also applicable to differential signaling.

At block 602, a signal is accepted at a signal input of an integrated circuit die. For example, a pin or pad for a signal input Rf.in of an integrated circuit die 502 can accept a signal 512. An amplifier die 304, for instance, may receive a signal 512 from a controller die 302.

At block 604, a supply voltage is accepted at a power input of the integrated circuit die. For example, a pin or pad for a power input (e.g., corresponding to a first power distribution node 432-1) of the integrated circuit die 502 can accept a supply voltage Vcc1. In some cases, the supply voltage Vcc1 may be coupled to a first node 402-1 of a Darlington circuit 138-1.

At block 606, an amplifier circuit amplifies, using a driver amplifier and the supply voltage, the signal to produce a first amplified signal. For example, an amplifier circuit 130 can amplify, using a driver amplifier 134 and the supply voltage Vcc1, the signal 512 to produce a first amplified signal 332-1. The signal 512 at a driver amplifier input of the driver amplifier 134 may be modified as compared to the signal 512 at the input of the integrated circuit die 502, such as by an input-matching network 322. To perform the driver amplification, a transistor 504 of the driver amplifier 134 may operate in a common-emitter mode (or a common-source mode for an FET) to accept the signal 512 at a base terminal (or gate terminal) and to provide the first amplified signal 332-1 at a collector terminal (or drain terminal) of the transistor 504.

At block 608, an amplifier circuit amplifies, using a power amplifier, an intermediate signal to produce a second amplified signal, with the intermediate signal at least based on the first amplified signal. For example, the amplifier circuit 130 can amplify, using a power amplifier 136, an intermediate signal 514 to produce a second amplified signal 332-2. Here, the intermediate signal 514 can at least be based on the first amplified signal 332-1. The intermediate signal 514, which can be applied to a power amplifier input of the power amplifier 136, can further comprise the first amplified signal 332-1 (e.g., if no architected components are coupled between a driver amplifier output of the driver amplifier 134 and the power amplifier input of the power amplifier 136). This power amplification may be performed by a power transistor of the power amplifier 136 that receives a same input power Vcc1 or a different input power Vcc2 and presents the second amplified signal 332-2 at a power amplifier output of the power amplifier 136.

At block 610, the supply voltage is clamped using two or more transistors that are coupled together in a Darlington transistor arrangement. For example, a power clamp 310 can clamp the supply voltage Vcc1 using two or more transistors 404 that are coupled together in a Darlington transistor configuration 408 (e.g., as depicted in FIG. 4). The clamping of the supply voltage Vcc1 may be performed using multiple diodes 406 that are coupled together in series and that establish a clamping voltage based on a quantity of the multiple diodes 406. Thus, a quantity of the multiple diodes 406 may set a trigger voltage for the power clamping in conjunction with turning on the Darlington configuration 408 of a Darlington circuit 138-1.

### Implementation Examples

This section describes some aspects of example implementations and/or example configurations related to the apparatuses and/or processes presented above.

Example aspect 1: An apparatus comprising:
an amplifier circuit including an input port and an output port, the amplifier circuit comprising:
   a driver amplifier including a driver amplifier output and a transistor, the driver amplifier coupled between the input port and the output port;
   a power amplifier including a power amplifier input, the power amplifier coupled between the driver amplifier output and the output port; and
   a Darlington circuit coupled to the driver amplifier via a node that is coupled between the input port and the power amplifier input.

Example aspect 2: The apparatus of example aspect 1, further comprising:
an integrated circuit die that comprises the amplifier circuit,
wherein the Darlington circuit is configured to provide electrostatic discharge (ESD) protection for the integrated circuit die.

Example aspect 3: The apparatus of example aspect 1 or 2, further comprising:
an integrated circuit die that comprises the amplifier circuit,
wherein the Darlington circuit is configured to provide power clamping for the integrated circuit die with respect to power that is supplied to the driver amplifier.

Example aspect 4: The apparatus of any one of the preceding example aspects, wherein the Darlington circuit is coupled to a power distribution node for the transistor of the driver amplifier.

Example aspect 5: The apparatus of example aspect 4, wherein the power distribution node comprises a supply voltage node.

Example aspect 6: The apparatus of any one of the preceding example aspects, wherein the Darlington circuit is coupled to a channel terminal of the transistor of the driver amplifier.

Example aspect 7: The apparatus of example aspect 6, wherein:
the transistor of the driver amplifier comprises a heterojunction bipolar transistor (HBT); and
the channel terminal comprises a collector terminal.

Example aspect 8: The apparatus of any one of the preceding example aspects, wherein:
the node is coupled between a driver amplifier input of the driver amplifier and the power amplifier input; and
the node corresponds to:
   a channel terminal of the transistor of the driver amplifier; and
   a supply voltage node for the transistor of the driver amplifier.

Example aspect 9: The apparatus of any one of the preceding example aspects, wherein the Darlington circuit comprises:
two or more transistors coupled together in a Darlington transistor arrangement, the Darlington transistor arrangement coupled between the node and a power distribution node.

Example aspect 10: The apparatus of example aspect 9, wherein the Darlington circuit comprises:
at least one diode,
wherein the Darlington transistor arrangement and the at least one diode are coupled together in series between the node and the power distribution node.

Example aspect 11: The apparatus of example aspect 9 or 10, wherein:
the two or more transistors comprise a first transistor and a second transistor; and
a channel terminal of the first transistor is coupled to a control terminal of the second transistor.

Example aspect 12: The apparatus of example aspect 11, wherein the Darlington circuit comprises:
multiple diodes coupled together in series between the node and a control terminal of the first transistor of the two or more transistors.

Example aspect 13: The apparatus of example aspect 12, wherein the Darlington circuit is configured to clamp a voltage at the node responsive to a voltage level that is based, at least partly, on a quantity of diodes of the multiple diodes.

Example aspect 14: The apparatus of example aspect 12 or 13, wherein the Darlington circuit is configured to increase a clamping action on a voltage at the node as the voltage at the node increases.

Example aspect 15: The apparatus of any one of example aspects 11-14, wherein the Darlington circuit comprises:
at least one diode coupled between a control terminal of the first transistor and the power distribution node.

Example aspect 16: The apparatus of example aspect 15, wherein the Darlington circuit comprises:
at least one resistor coupled in series with the at least one diode between the control terminal of the first transistor and the power distribution node.

Example aspect 17: The apparatus of any one of the preceding example aspects, further comprising:
a radio-frequency front-end comprising the amplifier circuit.

Example aspect 18: An apparatus comprising:
an amplifier circuit including an input port and an output port, the amplifier circuit comprising:
   a driver amplifier including a driver amplifier input, a driver amplifier output, and means for amplifying a signal, the driver amplifier coupled to the input port via the driver amplifier input;
   a power amplifier including a power amplifier input and a power amplifier output, the power amplifier coupled to the driver amplifier output via the power amplifier input and to the output port via the power amplifier output; and
   means for clamping a supply voltage of the means for amplifying a signal.

Example aspect 19: A method comprising:
accepting a signal at a signal input of an integrated circuit die;
accepting a supply voltage at a power input of the integrated circuit die;
amplifying, using a driver amplifier and the supply voltage, the signal to produce a first amplified signal;
amplifying, using a power amplifier, an intermediate signal to produce a second amplified signal, the intermediate signal at least based on the first amplified signal; and
clamping the supply voltage using two or more transistors that are coupled together in a Darlington transistor arrangement.

Example aspect 20: The method of example aspect 19, wherein the clamping comprises:
clamping the supply voltage using multiple diodes that are coupled together in series and that establish a clamping voltage based on a quantity of the multiple diodes.

### CONCLUSION

As used herein, the terms “couple,” “coupled,” or “coupling” refer to a relationship between two or more components that are in operative communication with each other to implement some feature or realize some capability that is described herein. The coupling can be realized using, for instance, a physical line, such as a metal trace or wire, or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “port” (e.g., including a “first port” or an “amplifier port”) represents at least a point of electrical connection at or proximate to the input or output of a component or between two or more components (e.g., active or passive circuit elements or parts). Although at times a port may be visually depicted in a drawing as a single point (or a circle), the port can represent an inter-connected portion of a physical circuit or network that has at least approximately a same voltage potential at or along the portion. In other words, a single-ended port can represent at least one point (e.g., a node) of multiple points along a conducting medium (e.g., a wire or trace) that exists between electrically connected components. In some cases, a “port” can represent at least one node that represents or corresponds to an input or an output of a component, such as a filter, amplifier circuit, or portion thereof. Similarly, a “terminal” or a “node” may represent one or more points with at least approximately a same voltage potential relative to an input or output of a component.

The terms “first,” “second,” “third,” and other numeric-related indicators are used herein to identify or distinguish similar or analogous items from one another within a given context—such as a particular implementation, a single drawing figure, a given component, or a claim. Thus, a first item in one context may differ from a first item in another context. For example, an item identified as a “first signal” in one context may be identified as a “second signal” in another context. Similarly, a “first port” or a “first transistor” in one claim may be recited as a “second port” or a “third transistor,” respectively, in a different claim.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing a Darlington circuit with a driver amplifier have been described in language specific to certain features and/or methods, the subject of the appended claims is not necessarily limited to the specific features or methods described. Rather, the specific features and methods are disclosed as example implementations for realizing a Darlington circuit with a driver amplifier.

What is claimed is:

1. An apparatus comprising:
an amplifier circuit including an input port and an output port, the amplifier circuit comprising:
a driver amplifier including a driver amplifier output and a transistor, the driver amplifier coupled between the input port and the output port;
a power amplifier including a power amplifier input, the power amplifier coupled between the driver amplifier output and the output port; and
a Darlington circuit coupled to the driver amplifier via a node that is coupled between the input port and the power amplifier input.

2. The apparatus of claim 1, further comprising:
an integrated circuit die that comprises the amplifier circuit,
wherein the Darlington circuit is configured to provide electrostatic discharge (ESD) protection for the integrated circuit die.

3. The apparatus of claim 1, further comprising:
an integrated circuit die that comprises the amplifier circuit,
wherein the Darlington circuit is configured to provide power clamping for the integrated circuit die with respect to power that is supplied to the driver amplifier.

4. The apparatus of claim 1, wherein the Darlington circuit is coupled to a power distribution node for the transistor of the driver amplifier.

5. The apparatus of claim 4, wherein the power distribution node comprises a supply voltage node.

6. The apparatus of claim 1, wherein the Darlington circuit is coupled to a channel terminal of the transistor of the driver amplifier.

7. The apparatus of claim 6, wherein:
the transistor of the driver amplifier comprises a heterojunction bipolar transistor (HBT); and
the channel terminal comprises a collector terminal.

8. The apparatus of claim 1, wherein:
the node is coupled between a driver amplifier input of the driver amplifier and the power amplifier input; and
the node corresponds to:
a channel terminal of the transistor of the driver amplifier; and
a supply voltage node for the transistor of the driver amplifier.

9. The apparatus of claim 1, wherein the Darlington circuit comprises:
two or more transistors coupled together in a Darlington transistor arrangement, the Darlington transistor arrangement coupled between the node and a power distribution node.

10. The apparatus of claim 9, wherein the Darlington circuit comprises:
at least one diode,
wherein the Darlington transistor arrangement and the at least one diode are coupled together in series between the node and the power distribution node.

11. The apparatus of claim 9, wherein:
the two or more transistors comprise a first transistor and a second transistor; and
a channel terminal of the first transistor is coupled to a control terminal of the second transistor.

12. The apparatus of claim 11, wherein the Darlington circuit comprises:
multiple diodes coupled together in series between the node and a control terminal of the first transistor of the two or more transistors.

13. The apparatus of claim 12, wherein the Darlington circuit is configured to clamp a voltage at the node responsive to a voltage level that is based, at least partly, on a quantity of diodes of the multiple diodes.

14. The apparatus of claim 12, wherein the Darlington circuit is configured to increase a clamping action on a voltage at the node as the voltage at the node increases.

15. The apparatus of claim 11, wherein the Darlington circuit comprises:
at least one diode coupled between a control terminal of the first transistor and the power distribution node.

16. The apparatus of claim 15, wherein the Darlington circuit comprises:
at least one resistor coupled in series with the at least one diode between the control terminal of the first transistor and the power distribution node.

17. The apparatus of claim 1, further comprising:
a radio-frequency front-end comprising the amplifier circuit.

18. An apparatus comprising:
an amplifier circuit including an input port and an output port, the amplifier circuit comprising:
a driver amplifier including a driver amplifier input, a driver amplifier output, and means for amplifying a signal, the driver amplifier coupled to the input port via the driver amplifier input;
a power amplifier including a power amplifier input and a power amplifier output, the power amplifier coupled to the driver amplifier output via the power amplifier input and to the output port via the power amplifier output; and
means for clamping a supply voltage of the means for amplifying a signal.

19. A method comprising:
accepting a signal at a signal input of an integrated circuit die;
accepting a supply voltage at a power input of the integrated circuit die;
amplifying, using a driver amplifier and the supply voltage, the signal to produce a first amplified signal;
amplifying, using a power amplifier, an intermediate signal to produce a second amplified signal, the intermediate signal at least based on the first amplified signal; and
clamping the supply voltage using two or more transistors that are coupled together in a Darlington transistor arrangement.

20. The method of claim 19, wherein the clamping comprises:
clamping the supply voltage using multiple diodes that are coupled together in series and that establish a clamping voltage based on a quantity of the multiple diodes.
